(19) United States
(12) Patent Application Publication
(10) Pub. No.: US 2008/0150097 A1
(43) Pub. Date: Jun. 26, 2008

(54) Semiconductor device with reduced power noise

(75) Inventor: Ki-Jae Song, Paju-si (KR)

Correspondence Address: MILLS & ONELLO LLP, ELEVEN BEACON STREET, SUITE 605, BOSTON, MA, 02108, US

(73) Assignee: Samsung Electronics, Co., Ltd., Suwon-si (KR)

(21) Appl. No.: 11/899,483

(22) Filed: Sep. 6, 2007

(30) Foreign Application Priority Data
Dec. 21, 2006 (KR) 10-2006-0132028

(51) Int. Cl. H01L 23/52

(52) U.S. Cl. 257/664; 257/E23.141

(57) ABSTRACT

Provided are a semiconductor device with reduced power noise, which can be used in a high-speed device with an operating frequency of at or above about 1 GHz and does not have any spatial restriction due to signal patterns or other structures. The semiconductor device includes a power panel, an insulating layer, and a stub unit. The power panel has electrical devices formed thereon. The insulating layer covers the power panel. The stub unit is formed on the insulating layer and has one or more fan-shaped stubs electrically connected to the power panel through a via contact penetrating the insulating layer.

### CROSS-REFERENCE TO RELATED PATENT APPLICATION

This application claims priority under 35 U.S.C. §119 to Korean Patent Application No. 10-2006-0132028, filed on Dec. 21, 2006, in the Korean Intellectual Property Office, the disclosure of which is incorporated herein in its entirety by reference.

### BACKGROUND OF THE INVENTION

1. Field of the Invention

The present invention relates to a semiconductor device, and more particularly, to a semiconductor device with reduced power noise.

2. Description of the Related Art

A multilayer substrate with printed circuit patterns becomes essential, as a variety of electronic products such as information appliances become miniaturized, lightweight and high in performance. The multilayer substrate has a multilayer structure of metal layers and insulating layers and constitutes an electrical system of an electronic product. It is required to remove power noise generated in the multilayer substrate.

In conventional methods, the power noise is removed by reducing the power impedance using a decoupling capacitor. Although the conventional methods can reduce the power impedance under conditions of an operating frequency of 100 MHz to 1 GHz by using the resonance characteristic of the decoupling capacitor, it cannot reduce the power impedance under conditions of an operating frequency of over 1 GHz.

FIG. 1 is a plan view illustrating an example of a conventional printed circuit board (PCB) with decoupling capacitors mounted thereon. FIG. 2 is a graph showing the relationship between impedance and frequency in the PCB of FIG. 1 when a power panel is excluded.

As illustrated in FIG. 1, a device 20 consuming a current is packaged on a substrate 10, and a plurality of capacitors C1 through C6 having different capacitances are connected in parallel near the device 20. The capacitors C1 through C6 can be ceramic capacitors, and are disposed nearest the device 20. A reference numeral 30 denotes a point where a current sinks.

The power noise is reduced by the resonance characteristics of the capacitors C1 through C6 by disposing the capacitors C1 through C6 near the device 20. However, when the capacitors C1 through C6 with different capacitances are connected in parallel, a plurality of resonances are generated as shown at a portion “a” in FIG. 2. Each of the capacitors C1 through C6 has characteristics that vary greatly according to its position, and has different tolerance in its capacitance. Thus, it is difficult to obtain the same resonance. Particularly, as illustrated in FIG. 2, it is difficult to remove the power noise in a high-speed device with an operating frequency of over 1 GHz by using the capacitors C1 through C6. Moreover, because of signal patterns or other structures, it is difficult to dispose the capacitors C1 through C6 nearest the device 20.

### SUMMARY OF THE INVENTION

In accordance with the present invention, there is provided a semiconductor device with reduced power noise, which can be used in a high-speed device with an operating frequency of over 1 GHz and does not have any spatial restriction due to signal patterns or other structures.

According to an aspect of the present invention, there is provided a semiconductor device with reduced power noise, the semiconductor device including: a power panel having electrical devices formed thereon; an insulating layer formed on the power panel; and a stub unit formed on the insulating layer and having one or more fan-shaped stubs electrically connected to the power panel through a via contact penetrating the insulating layer.

The power panel can be a printed circuit board (PCB).

Decoupling capacitors can be disposed on the power panel.

The via contact can be formed perpendicular to the power panel.

The fan-shaped stubs can extend radially from the via contact centered therebetween.

The fan-shaped stubs can be configured such that an adjustment to the radii causes a corresponding adjustment to the frequencies at which impedances are reduced.

The stub unit can comprise two or more fan-shaped stubs having different radii.

The stub unit can comprise two or more fan-shaped stubs having the same radius.

Each of the one or more fan-shaped stubs can have a radius corresponding to ¼ of an effective wavelength.

The radii of the one or more fan-shaped stubs can be determined for impedance reductions in a predetermined frequency band.

The predetermined frequency band can include an operating frequency at or above about 1 GHz.

Angle distances between the fan-shaped stubs can be determined according to frequencies at which impedances are to be reduced.

According to another aspect of the present invention, there is provided a semiconductor device with reduced power noise, the semiconductor device including: a first insulating layer; a power panel formed on a surface of the first insulating layer and having electrical devices formed thereon; a second insulating layer formed on the power panel; a stub unit formed on the second insulating layer and having one or more fan-shaped stubs electrically connected to the power panel through a via contact penetrating the second insulating layer; and a third insulating layer formed on and protecting the stub unit.

The via contact can be formed perpendicular to the power panel.

The fan-shaped stubs can comprise more two or more fan-shaped stubs and that extend radially from the via contact centered therebetween.

The stub unit can have two or more fan-shaped stubs having different radii.

The stub unit can have two or more fan-shaped stubs having the same radius.

Each of the fan-shaped stubs can have a radius corresponding to ¼ of an effective wavelength.

The radii of the fan-shaped stubs can be determined for impedance reductions at a predetermined frequency band.

The predetermined frequency band can include an operating frequency at or above about 1 GHz.

### BRIEF DESCRIPTION OF THE DRAWINGS

The present invention will become more apparent in view of the attached drawings and accompanying detailed description. The embodiments depicted therein are provided by way of example, not by way of limitation, wherein like reference numerals refer to the same or similar elements. In the drawings:

FIG. 1 is a plan view illustrating an example of a prior art PCB with decoupling capacitors mounted thereon;

FIG. 2 is a graph showing the relationship between impedance and frequency in the PCB of FIG. 1 when a power panel is excluded;

FIG. 3 is a sectional view of an embodiment of a semiconductor device with reduced power noise according to aspects of the present invention;

FIG. 4 is a plan view illustrating an embodiment of a general structure of a stub unit in FIG. 3;

FIG. 5 is a plan view of an embodiment of a first power panel according to aspects of the present invention;

FIG. 6 is a graph showing the relationship between impedance and frequency when one or more capacitors are added to the first power panel in FIG. 5;

FIG. 7 is a plan view of an embodiment of a second power panel including another embodiment of a stub unit according to an aspect of the present invention;

FIG. 8 is a graph showing the relationship between impedance and frequency in accordance with FIG. 7;

FIG. 9 is a plan view of an embodiment of a second power panel including another embodiment of a stub unit according to another aspect of the present invention;

FIG. 10 is a graph showing the relationship between impedance and frequency in accordance with FIG. 9;

FIG. 11 is a plan view of an embodiment of a second power panel including another embodiment of a stub unit according to a modification of the another aspect of the present invention;

FIG. 12 is a graph showing the relationship between impedance and frequency in accordance with FIG. 11;

FIG. 13 is a plan view of an embodiment of a second power panel including another embodiment of a stub unit according to another modification of the another aspect of the present invention; and

FIG. 14 is a graph showing the relationship between impedance and frequency in accordance with FIG. 13.

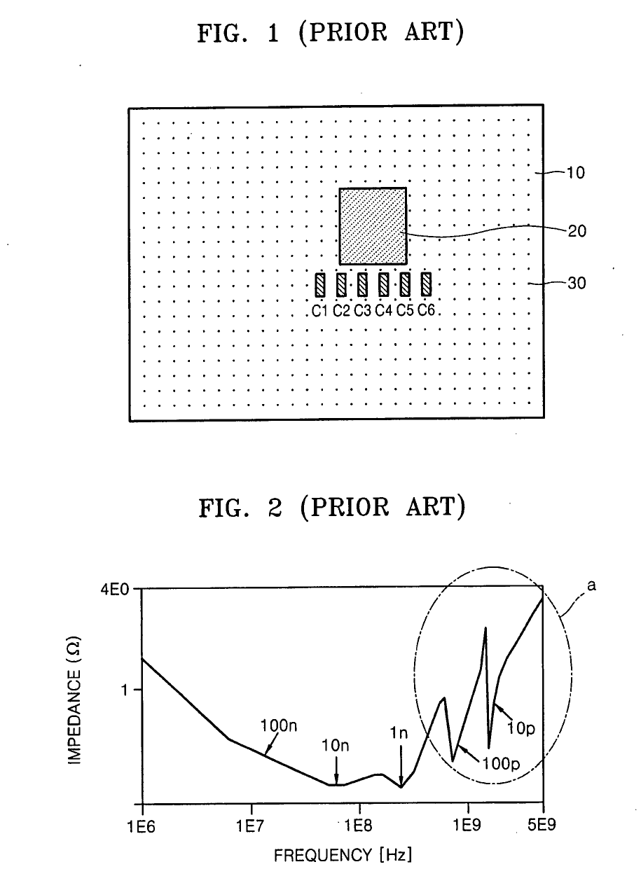

### DETAILED DESCRIPTION OF THE INVENTION

The present invention will now be described more fully with reference to the accompanying drawings, in which exemplary embodiments in accordance with aspects of the present invention are shown. The invention can, however, be embodied in many different forms and should not be construed as being limited by the embodiments set forth herein.

It will be understood that, although the terms first, second, etc. may be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements may be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

The embodiments in accordance with aspects of the present invention provide a stub unit having fan-shaped stubs for reducing power noise at desired frequencies. Reducing the power noise means that the power noise is minimized and impedance is stably reduced at the desired frequency. To this end, the characteristics of the stub unit will be first described, and effects on the power noise will be described according to the possible shapes of the stub unit.

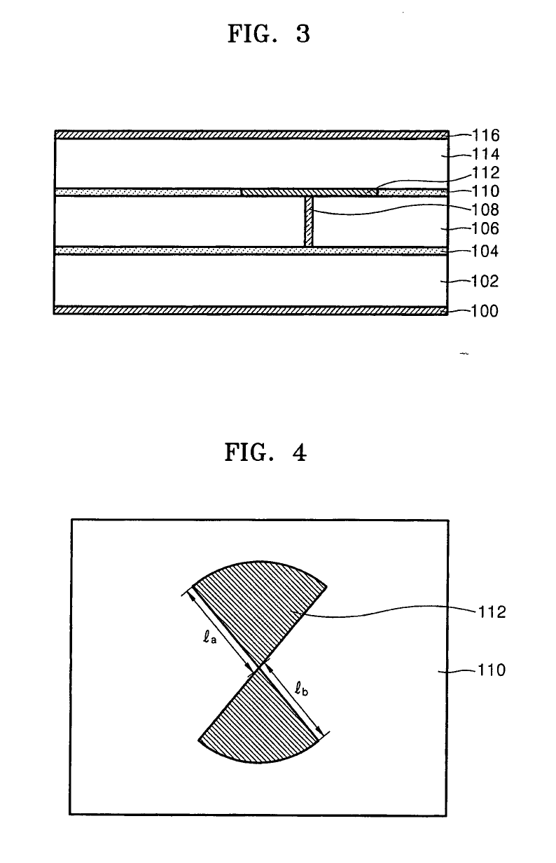

FIG. 3 is a sectional view of an embodiment of a semiconductor device configured to achieve the desired reduced power noise, in accordance with aspects of the present invention. FIG. 4 is a plan view illustrating an embodiment of a general structure of a stub unit in FIG. 3 in accordance with aspects of the present invention. Generally, the semiconductor device with reduced power noise will be simply referred to as the “power noise reduction device”.

Referring to FIGS. 3 and 4, the semiconductor device includes a first power panel 104 interposed between a first insulating layer 102 and a second insulating layer 106, and a second power panel 110 interposed between the second insulating layer 106 and a third insulating layer 114. The first power panel 104 can be a general printed circuit board (PCB). The second power panel 110 can be a PCB in which the stub unit 112 of the present invention is disposed. The stub unit 112 can be electrically connected to the first power panel 104 through a via contact 108 penetrating the second insulating layer 106. The third insulating layer 114 covers and protects the second power panel 110 and the stub unit 112. Ground layers 100 and 116 are formed on exposed surfaces of the first insulating layer 102 and the third insulating layer 114, respectively.

Referring FIG. 4, the stub unit 112 has two fan-shaped stubs that extend radially from the via contact 108 centered therebetween. The fan-shaped stubs can have different radii. Each of the fan-shaped stubs can have a radius of λ/4 corresponding to ¼ of an effective wavelength λ. The effective wavelength λ is a wavelength of a frequency at which impedance is to be reduced. For example, the stub unit 112 can have a first fan-shaped stub with a radius lₐ corresponding to ¼ of an effective wavelength λₐ and a second fan-shaped stub with a radius l_{b} corresponding to ¼ of an effective wavelength λ_{b}. Since resonance frequencies vary with a change in the radii of the two fan-shaped stubs, impedances at a desired frequency band can be easily reduced by changing the radii of the two fan-shaped stubs.

The stub unit 112 can be disposed nearest to the first power panel 104, rather than to the ground layers 100, 116. The stub unit 112 is disposed nearest the first power panel 104 and within the separate second power panel 110 in order to reduce the power noise without reference to effects of signal patterns and other structures. To this end, the via contact 108 used to connect the stub unit 112 to the first power panel 104 is formed to be substantially perpendicular to the stub unit 112 and the first power panel 104, in the present embodiment.

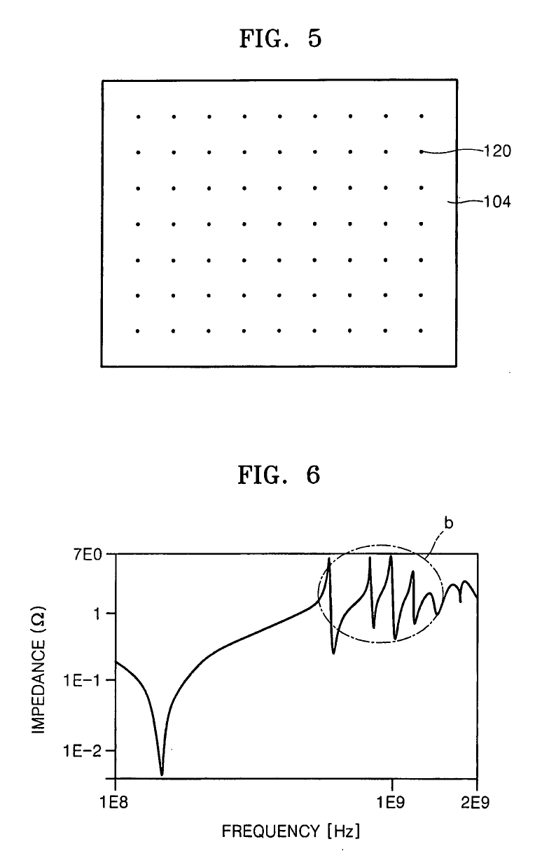

FIG. 5 is a plan view of an embodiment of a first power panel 104 (e.g., a PCB) according to an aspect of the present invention. FIG. 6 is a graph showing the relationship between impedance and frequency when one or more capacitors are added to the first power panel 104 in FIG. 5.

Referring to FIGS. 5 and 6, impedance in a frequency band below 1 GHz can be reduced when one or more capacitors are disposed at points 120, i.e., where a current sinks. However, an impedance greatly increases near a frequency band “b” of about 1 GHz, so it is impossible to obtain uniform impedance-reduction characteristics. That is, the uniform characteristic cannot be achieved due to an inductor component of the capacitor, so that the impedance reduction for reducing the power noise cannot be uniformly obtained. In addition, because of various structures that tend to be formed on the first power panel 104, it is difficult to physically attach the capacitors for the impedance reduction.

In the embodiments herein, a separate insulating layer (e.g., the second insulating layer 106 of FIG. 3) is used and the stub unit 112 is formed in the second power panel 110, as illustrated in FIG. 3, in order to reduce the power noise at desired frequencies that is caused when the capacitors are attached directly to the first power panel 104. Accordingly, the uniform impedance-reduction characteristics can be obtained, and the stub unit 112 can be disposed at a desired position.

In the following embodiments, a power noise reduction effect is described according to the shapes of stub units. For convenience of description, a separate reference numeral is given to each of the stub units. When necessary, decoupling capacitors can be disposed on the first power panel 104 that is electrically connected to the second power panel 110, which includes the stub unit. That is, the decoupling capacitors can be disposed on the first power panel 104, and a stub unit, which will be described below, can be disposed within the second power panel 110. In some cases, decoupling capacitors need not be disposed on the first power panel 104.

### EMBODIMENT 1

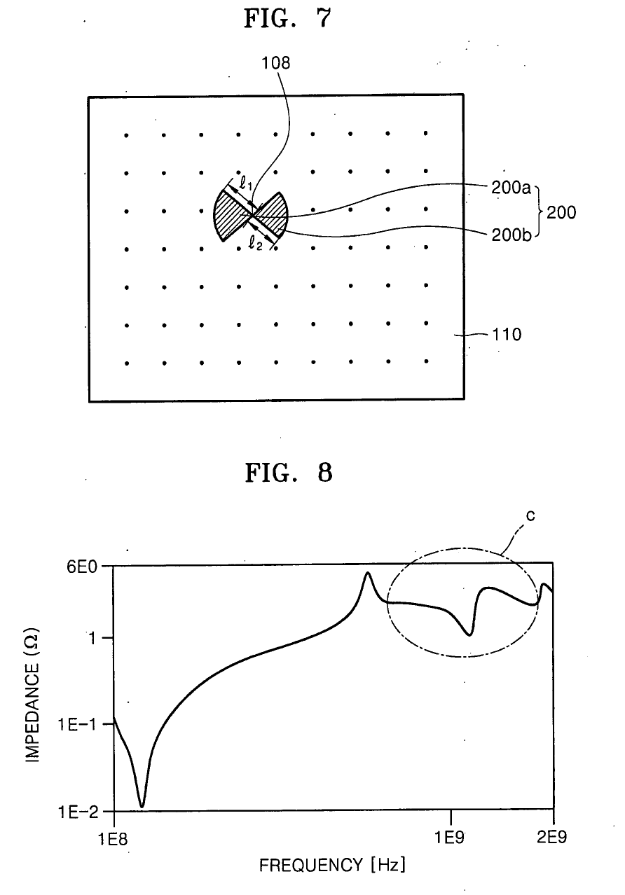

FIG. 7 is a plan view of a second power panel 110 including an embodiment of a stub unit 200 according to an aspect of the present invention. FIG. 8 is a graph showing the relationship between impedance and frequency in accordance with the device of FIG. 7. Except for the stub unit 200, a structure of a power noise reduction device in the present embodiment is substantially similar to that of FIG. 3. In the present embodiment, the stub unit 200 has two fan-shaped stubs 200a and 200b disposed in the second power panel 110.

Referring FIGS. 7 and 8, the fan-shaped stubs 200a and 200b extend radially from the exposed via contact 108 centered therebetween. The fan-shaped stub 200a has a radius l₁ corresponding to ¼ of an effective wavelength λ₁, and the fan-shaped stub 200b has a radius l₂ corresponding to ¼ of an effective wavelength λ₂.

Since resonance frequencies vary with a change in radii of the fan-shaped stubs 200a and 200b, impedances at a desired frequency band can be easily reduced by changing the radii of the fan-shaped stubs 200a and 200b. A stable impedance-reduction characteristic can be obtained near 1 GHz (at portion “c”) as shown FIG. 8. An angular distance between the fan-shaped stubs 200a and 200b can be adjusted according to the impedance-reduction characteristic.

### EMBODIMENT 2

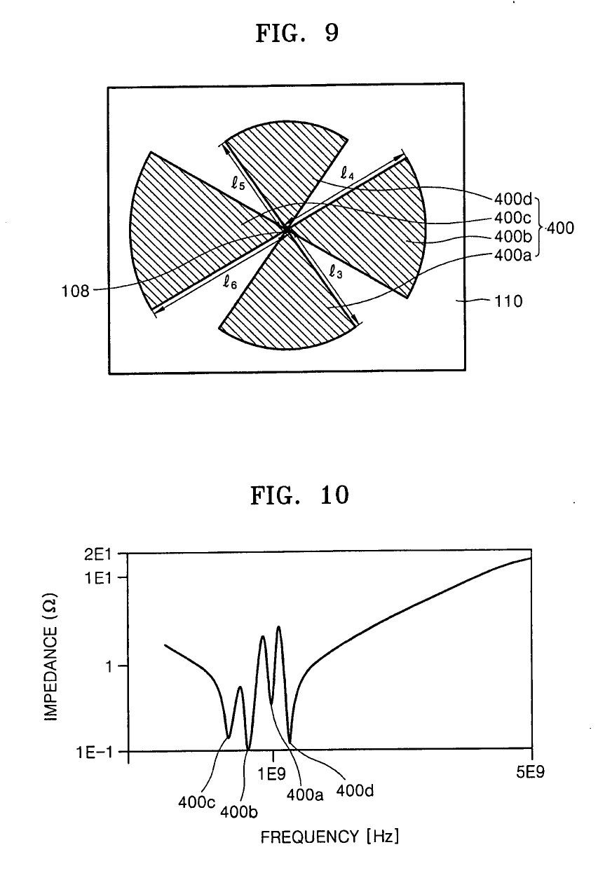

FIG. 9 is a plan view of a second power panel 110 including an embodiment of a stub unit 400 according to another aspect of the present invention. FIG. 10 is a graph showing the relationship between impedance and frequency in accordance with the device of FIG. 9. Except for the stub unit 400, a structure of a power noise reduction device in this embodiment is substantially similar to that of FIG. 3. In the this embodiment, the stub unit 400 has four fan-shaped stubs 400a, 400b, 400c, and 400d disposed in the second power panel 110.

Referring FIGS. 9 and 10, the fan-shaped stubs 400a, 400b, 400c, and 400d extend radially from the exposed via contact 108 centered therebetween. The fan-shaped stub 400a has a radius l₃ corresponding to ¼ of an effective wavelength λ₃, the fan-shaped stub 400b has a radius l₄ corresponding to ¼ of an effective wavelength λ₄, the fan-shaped stub 400d has a radius l₄ corresponding to ¼ of an effective wavelength λ₅, and the fan-shaped stub 400c has a radius l₆ corresponding to ¼ of an effective wavelength λ₆. The four radii maintain the relationship of l₅<l₃<l₄<l₆.

Since resonance frequencies vary with a change in radii of the fan-shaped stub 400a, 400b, 400c, and 400d, impedances at a desired frequency band can be easily reduced by changing the radii of the fan-shaped stubs 400a, 400b, 400c, and 400d. The impedance reduction characteristics according to the fan-shaped stubs 400a, 400b, 400c and 400d can be obtained near 1 GHz as shown FIG. 10. The desired frequencies in another embodiment of the present are 700-1200 MHz. As illustrated in FIG. 10, as the radius of the stub unit 400 increases, the frequency, at which impedance is reduced, decreases. An angular distance between the fan-shaped stubs 400a, 400b, 400c and 400d can be adjusted according to the impedance-reduction characteristics.

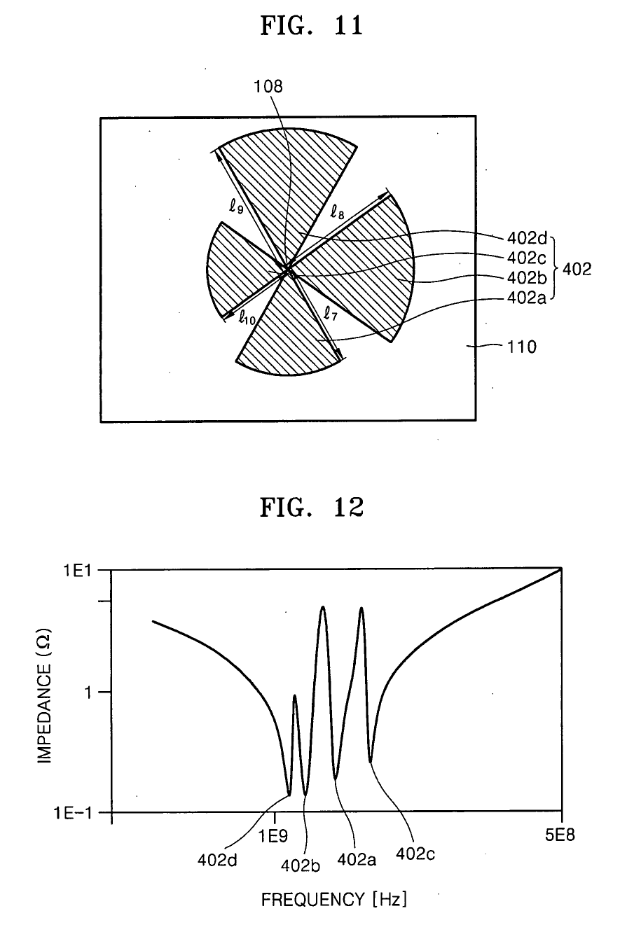

FIG. 11 is a plan view of a second power panel 110 including another embodiment of a stub unit 402, as a modification of the embodiment of FIG. 9. FIG. 12 is a graph showing the relationship between impedance and frequency in accordance with FIG. 11. Except for the stub unit 402, a structure of a power noise reduction device in this embodiment is substantially similar to that of FIG. 3. In the modification, the stub unit 402 has four fan-shaped stubs 402a, 402b, 402c, and 402d disposed in the second power panel 110.

Referring FIGS. 11 and 12, the fan-shaped stubs 402a, 402b, 402c, and 402d extend radially from the exposed via contact 108 centered therebetween. The fan-shaped stub 402a has a radius l₇ corresponding to ¼ of an effective wavelength λ₇, the fan-shaped stub 402b has a radius l₈ corresponding to ¼ of an effective wavelength λ₈, the fan-shaped stub 402d has a radius l₉ corresponding to ¼ of an effective wavelength λ₉, and the fan-shaped stub 402c has a radius l₁₀ corresponding to ¼ of an effective wavelength λ₁₀. The four radii maintain the relationship of l₁₀<l₇<l₈<l₉.

Since resonance frequencies vary with a change in radii of the fan-shaped stubs 402a, 402b, 402c and 402d, impedances at a desired frequency band can be easily reduced by changing the radii of the fan-shaped stubs 402a, 402b, 402c and 402d. The impedance-reduction characteristics according to the fan-shaped stubs 402a, 402b, 402c and 402d can be obtained near 1 GHz as shown FIG. 12. The desired frequencies in the modification are 1200-2000 MHz, in this embodiment. As illustrated in FIG. 12, as the radius of the stub unit 402 increases, the frequency, at which impedance is reduced, decreases. In addition, frequencies, at which impedances are reduced, can be selected by using the fan-shaped stubs 402a, 402b, 402c, and 402d having different radii.

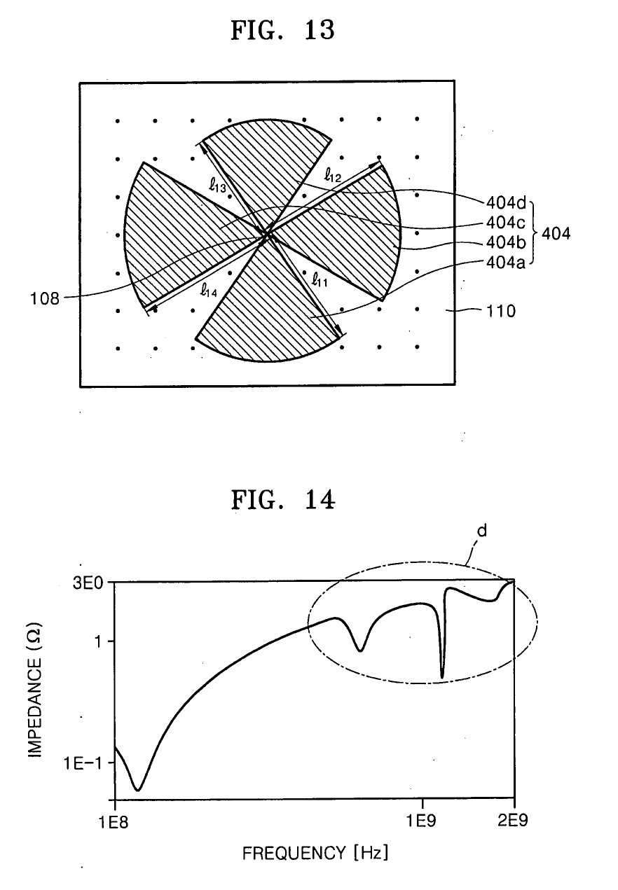

FIG. 13 is a plan view of a second power panel 110 including another embodiment of a stub unit 404, as a modification to the other embodiments of FIGS. 9 and 11. FIG. 14 is a graph showing the relationship between impedance and frequency in accordance with the device of FIG. 13. Except for the stub unit 404, a structure of a power noise reduction device in this embodiment is substantially similar to that of FIG. 3. In this embodiment, the stub unit 404 has four fan-shaped stubs 404a, 404b, 404c, and 404d disposed in the second power panel 110.

Referring FIGS. 13 and 14, the fan-shaped stubs 404a, 404b, 404c, and 404d extend radially from the exposed via contact 108 centered therebetween. The fan-shaped stub 404a has a radius l₁₁ corresponding to ¼ of an effective wavelength λ₁₁, the fan-shaped stub 404b has a radius l₁₂ corresponding to ¼ of an effective wavelength λ₁₂, the fan-shaped stub 404d has a radius l₁₃ corresponding to ¼ of an effective wavelength λ₁₃, and the fan-shaped stub 404c has a radius l₁₄ corresponding to ¼ of an effective wavelength λ₁₄. The four radii maintain the relationship of l₁₃<l₁₁<l₁₂<l₁₄. But the sizes of l₁₁, l₁₂ and l₁₄ in this embodiment are different from their respective counterparts in the prior two embodiments of FIGS. 9 and 11.

Since resonance frequencies vary with a change in radii of the fan-shaped stubs 404a, 404b, 404c, and 404d, impedances at a desired frequency band can be easily reduced by changing the radii of the fan-shaped stubs 404a, 404b, 404c, and 404d. The impedance reduction characteristics according to the fan-shaped stubs 404a, 404b, 404c, and 404d can be obtained near 1 GHz (at portion “d”) as shown FIG. 14. As illustrated in FIG. 14, as the radius of the stub unit 404 increases, the frequency, at which impedance is reduced, decreases. In addition, the magnitude of the difference between the radii of the fan-shaped stubs 404a, 404b, 404c, and 404d is smaller than that in the modification. Thus, the impedance reduction can be more stably achieved.

Although not explicitly described, a stable power noise reduction device can be obtained by using a plurality of fan-shaped stubs with the same radius. A fan-shaped stub with a relatively large radius is needed to achieve impedance reduction at a frequency below 1 GHz. Therefore, if there is no structural restriction, the impedance reduction at a frequency below 1 GHz can be achieved by increasing the radius of the stub unit.

As described above, in the power noise reduction device according to aspects of the present invention, the stub unit for the power noise reduction is formed separately from the PCB. Accordingly, the stable power noise reduction effect can be achieved and the stub unit can be formed at a desired location.

While the present invention has been particularly shown and described with reference to exemplary embodiments, it will be understood by those of ordinary skill in the art that various changes in form and details can be made therein without departing from the spirit and scope of the present invention as defined by the following claims. Although the stub units with two or more fan-shaped stubs are used in the embodiments herein, the objects of the present invention can be achieved using one fan-shaped stub. It is intended by the following claims to claim that which is literally described and all equivalents thereto, including all modifications and variations that fall within the scope of each claim.

What is claimed is:

1. A semiconductor device with reduced power noise, the semiconductor device comprising:
a power panel having electrical devices formed thereon;
an insulating layer formed on the power panel; and
a stub unit formed on the insulating layer and having one or more fan-shaped stubs electrically connected to the power panel through a via contact penetrating the insulating layer.

2. The semiconductor device of claim 1, wherein the power panel is a printed circuit board (PCB).

3. The semiconductor device of claim 1, wherein decoupling capacitors are formed on the power panel.

4. The semiconductor device of claim 1, wherein the via contact is formed perpendicular to the power panel.

5. The semiconductor device of claim 1, wherein the one or more fan-shaped stubs extend radially from the via contact.

6. The semiconductor device of claim 1, wherein the fan-shaped stubs are configured such that configured such that an adjustment to the radii causes a corresponding adjustment to the frequencies at which impedances are reduced.

7. The semiconductor device of claim 1, wherein the stub unit comprises two or more fan-shaped stubs having different radii.

8. The semiconductor device of claim 1, wherein the stub unit comprises two or more fan-shaped stubs having the same radius.

9. The semiconductor device of claim 1, wherein each of the one or more fan-shaped stubs has a radius corresponding to ¼ of an effective wavelength.

10. The semiconductor device of claim 1, wherein the radii of the one or more fan-shaped stubs are determined for impedance reductions in a predetermined frequency band.

11. The semiconductor device of claim 10, wherein the predetermined frequency band includes an operating frequency at or above about 1 GHz.

12. The semiconductor device of claim 1, wherein angle distances between the fan-shaped stubs are determined according to frequencies at which impedances are to be reduced.

13. A semiconductor device with reduced power noise, the semiconductor device comprising:
a first insulating layer;
a power panel formed on a surface of the first insulating layer and having electrical devices formed thereon;
a second insulating layer formed on the power panel;
a stub unit formed on the second insulating layer and having one or more fan-shaped stubs electrically connected to the power panel through a via contact penetrating the second insulating layer; and
a third insulating layer formed on and protecting the stub unit.

14. The semiconductor device of claim 13, wherein the via contact is formed perpendicular to the power panel.

15. The semiconductor device of claim 13, wherein the fan-shaped stubs can comprise more two or more fan-shaped stubs that extend radially from the via contact centered therebetween.

16. The semiconductor device of claim 13, wherein the stub unit has two or more fan-shaped stubs having different radii.

17. The semiconductor device of claim 13, wherein the stub unit has two or more fan-shaped stubs having the same radius.

18. The semiconductor device of claim 13, wherein each of the fan-shaped stubs has a radius corresponding to ¼ of an effective wavelength.

19. The semiconductor device of claim 13, wherein the radii of the fan-shaped stubs are determined for impedance reductions at a predetermined frequency band.

20. The semiconductor device of claim 19, wherein the predetermined frequency band includes an operating frequency at or above about 1 GHz.
